(19) United States
(12) Patent Application Publication
(10) Pub. No.: US 2026/0309317 A1
(43) Pub. Date: Oct. 8, 2026

(54) Light Emitting Devices and Lighting Systems

(71) Applicant: Bridgelux, Inc., Fremont, CA (US)

(72) Inventor: Yi-Qun Li, Danville, CA (US)

(73) Assignee: Bridgelux, Inc., Fremont, CA (US)

(21) Appl. No.: 19/639,055

(22) Filed: Apr. 3, 2026

Related U.S. Application Data
(60) Provisional application No. 63/783,890, filed on Apr. 4, 2025.

(51) Int. Cl. F21V 23/00; F21V 9/30; F21V 19/00; F21Y 105/14; F21Y 115/10; H05B 45/30

(52) U.S. Cl. CPC F21V 23/005; F21V 9/30; F21V 19/001; H05B 45/30; F21Y 2105/14; F21Y 2115/10

(57) ABSTRACT

A light emitting device comprising: a substrate; and a string of serially connected LED chips on the substrate, wherein the light emitting device is configured for operation with a drive voltage in a range from 200 V to 500 V.

### CROSS REFERENCE TO RELATED APPLICATIONS

This application claims the benefit of priority to U.S. Provisional application No. 63/783,890, filed 4 Apr. 2025 which is hereby incorporated by reference in its entirety.

### FIELD OF THE INVENTION

Embodiments of the invention concern light emitting devices and lighting systems based on Light Emitting Diode (LED) chips/dies and in particular concerns light emitting devices comprising multiple LEDs. More particularly, although not exclusively, the invention concerns Chip-on-Board (CoB) light emitting devices.

### BACKGROUND OF THE INVENTION

Due to their long operating life expectancy and high lumen (luminous) efficacy (e.g., 100 lumens per watt and higher), light emitting devices based on LEDs are rapidly replacing conventional fluorescent, compact fluorescent and incandescent lamps.

Luminous efficacy is a measure of how well a light source generates visible light and is the ratio of luminous flux to power and has units of lumens per watt (lm/W). The power can be either the radiant power of light generated by the source or electrical power consumed by the source. When the power is the radiant power, the luminous efficacy is referred to as the Luminous Efficacy of Radiation (LER), often simply referred to as Luminous Efficacy (LE), and has units of lm/Wₒₚₜ. When the power is electrical power, the luminous efficacy is referred to as the Overall Luminous Efficacy (OLE) of the light source or luminous efficacy of a source and has units of lm/W_{dc}.

A CoB LED is a type of LED packaging comprising a thermally conductive substrate, for example a Metal core PCB (MPCB), having an array of LED chips (dies) mounted on the substrate. A phosphor material is dispensed over the array of LED chips to convert at least a part of the light generated by the LED chips to white light of a selected color temperature. Since the LED chips are unpackaged, this enables a high packing density of chips per unit area on the substrate. Such close packing of LED chips enables CoB LEDs to generate light with a high intensity density per unit area.

The present invention arose in an endeavor to improve the lumen (luminous) efficacy of CoB LEDs.

### SUMMARY OF THE INVENTION

Embodiments of the invention concern light emitting devices, for example CoB (Chip-on-Board) LEDs, and lighting systems that are configured for operation with high drive voltages, for example 200 V to 500 V. The configuration of the light emitting devices makes it particularly suitable for a Chip-on-Board device since close packing of LED chips enables CoB LEDs to generate light with a high intensity density per unit area and with a superior lumen efficacy than known devices.

According to an aspect of the invention, a light emitting device comprises: a substrate; and a string of serially connected LED chips/dies on the substrate (for instance, mounted on the substrate), wherein the light emitting device is configured for operation with a drive voltage in a range from 200 V to 500 V. The inventor has determined that by configuring a light emitting device for operation with a drive voltage in a range from 200 V to 500 V can result in an improvement in lumen (luminous) efficacy of about 10% compared with known light emitting devices that operate, for example, with a drive voltage of 32 V to 36 V. It is understood that the higher drive voltage in combination with a corresponding reduction in drive current results in a superior (higher) lumen (luminous) efficacy of the device compared with known constructions. Furthermore, a driver for generating a higher drive voltage and lower drive current to operate the device can be more efficient thereby contributing to the increase in lumen efficacy of the device. It may be that the light emitting device is configured for operation with a drive voltage that is inversely related to the drive current. It may be that the light emitting device is configured for operation with a drive current in a range from 50 mA to 5 mA.

In embodiments and depending on the selected drive voltage, the first plurality of LED chips can comprise from 65 to 195 serially connected LED chips/dies. The forward voltage drop, V_{f}, across each LED chip may be from 2.6 V to 3.1 V and may depend on the drive current. For example, for devices configured for operation with a lower drive voltage (for example, 200 V), the forward voltage drop across each LED chip may be about 3.0 V to 3.1 V. Conversely, for devices configured for operation with a higher drive voltage (for example, 500V), the forward voltage drop across each LED chip may be from about 2.6 V to 2.7 V.

The light emitting device may comprise a phosphor material at least partially covering the string of serially connected LED chips/dies.

In embodiments, the light emitting device can comprise a further string of serially connected LED chips on the substrate (for instance, mounted on the substrate). The string and further string of serially connected LED chips may comprise substantially a same number of LED chips/dies enabling the string and further string of serially connected LED chips/dies to be operated with the same drive voltage. The string and further string of serially connected LED chips may be connected in parallel.

In other embodiments, the string and further string of serially connected LED chips may comprise a different number of LED chips/dies.

In embodiments, the light emitting device may have a lumen (luminous) efficacy of at 120 lm/W, optionally at least 160 lm/W, and optionally may have a lumen efficacy of at least 180 lm/W.

The light emitting device may further comprise a driver for generating the drive voltage in a range from 200 V to 500 V. The driver can be configured for a nominal AC input voltage ranging from 100 V to 300 V. The driver may have an efficiency of at least 80%, optionally may have an efficiency of at least 90%.

According to another aspect of the invention, there is contemplated a lighting system comprising: a light emitting device; and a driver for generating a drive voltage in a range from 200V to 500V; wherein the light emitting device comprises: a substrate; and a string of serially connected LED chips on the substrate (for instance, mounted on the substrate), wherein the light emitting device is configured for operation with a drive voltage in a range from 200 V to 500 V and wherein the device has a lumen (luminous) efficacy of at least 120 lm/W and is for generating light of a CRI80 and a color temperature from 2700K to 6500K.

The lighting system can have a lumen efficacy of at least 160 lm/W, and optionally at least 180 lm/W.

The driver may have an efficiency of at least 80%.

In embodiments, the driver may be configured to generate a drive voltage from 400 V to 480 V and may have an efficiency of at least 90%. For a drive voltage in a range from 400 V to 480 V, the string of serially connected LED chips may comprise from 154 to 185 LED chips depending on the drive voltage. For a drive voltage of about 450V, the string of serially connected LED chips may comprise about 165 LED chips.

The driver can be configured for operation with a nominal AC input voltage in a range from 100 VAC to 300 VAC.

The string of serially connected LED chips may comprise from 77 to 192 LED chips.

The light emitting device may comprise a phosphor material at least partially covering the string of LED chips.

The light emitting device may comprise a further string of serially connected LED chips on the substrate (for instance, mounted on the substrate).

The string and further string of serially connected LED chips may comprise substantially a same number of LED chips/dies enabling the string and further string of serially connected LED chips/dies to be operated with the same drive voltage. The string and further string of serially connected LED chips can be connected in parallel.

In other embodiments, the string and further string of serially connected LED chips may comprise a different number of LED chips/dies.

The lighting system may further comprise an optical element comprising at least one of: a lens, a diffuser, and/or a parabolic reflector. The lighting system may comprise an optics holder. The optics holder may be for connecting the optical element to the lighting system.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, in which:

FIGS. 1A and 1B is a light emitting device, CoB LED, according to an embodiment of the invention in which FIG. 1A is a plan view of a light emitting device, FIG. 1B is a plan view of the device of FIG. 1B without phosphor showing the layout of the LED chips;

FIG. 2 is a plan view of a light emitting device, CoB LED, without phosphor showing the layout of the LED chips, according to an embodiment of the invention;

FIGS. 3A and 3B illustrate electrical arrangements of LEDs of light emitting devices according to embodiments of the invention;

FIG. 4 is a lighting arrangement according to an embodiment of the invention; and

FIGS. 5 to 7 are plan views of light emitting devices, CoB LEDs, without phosphor showing the layout of the LED chips, according to embodiments of the invention.

### DETAILED DESCRIPTION OF THE INVENTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Throughout this specification, like reference numerals preceded by the figure number are used to denote like features.

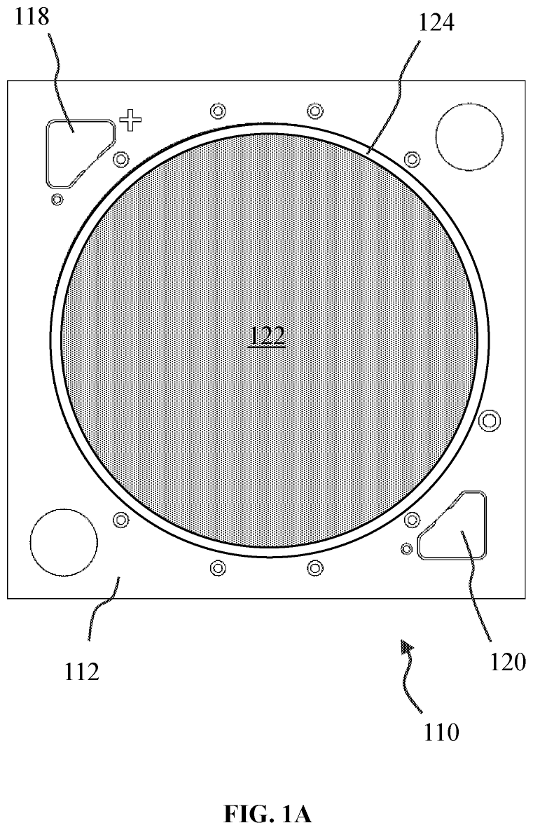

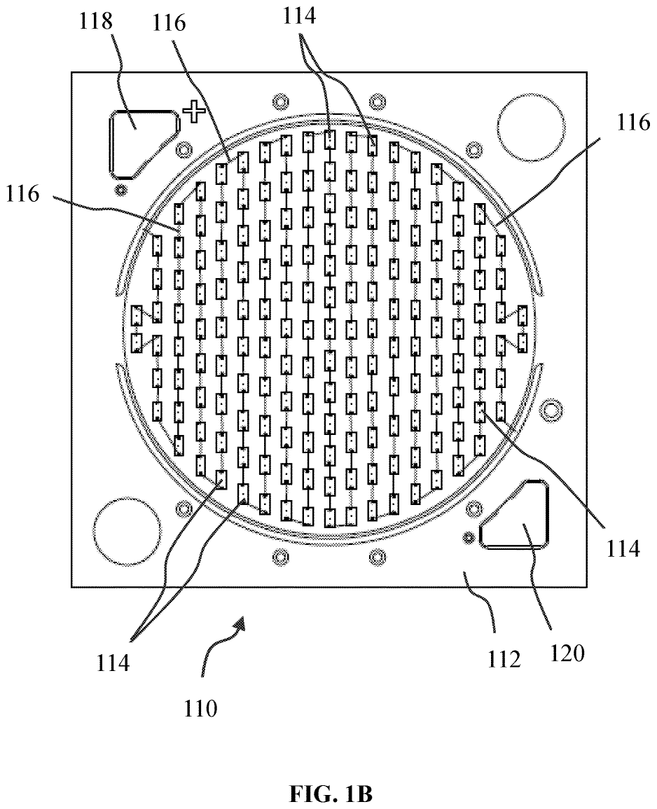

Referring to FIGS. 1A and 1B, there is shown a light emitting device 110, CoB LED, according to an embodiment of the invention in which FIG. 1A is a plan view of a light emitting device and FIG. 1B is a plan view of the device 110 without phosphor/annular wall showing the layout of LED chips. The light emitting device 110 is configured for operation with a nominal drive voltage of 450 V (Table 4) and to generate light with a color temperature from 2700K to 6500K.

The light emitting device 110 comprises a thermally conductive substrate 112 which may comprise aluminum with an insulating layer and electrically conducting traces on a top face. As illustrated, the substrate may be square and may be 24 mm by 24 mm (Table 4). Of course, it will be understood, the substrate may be a different shape and perform the same function.

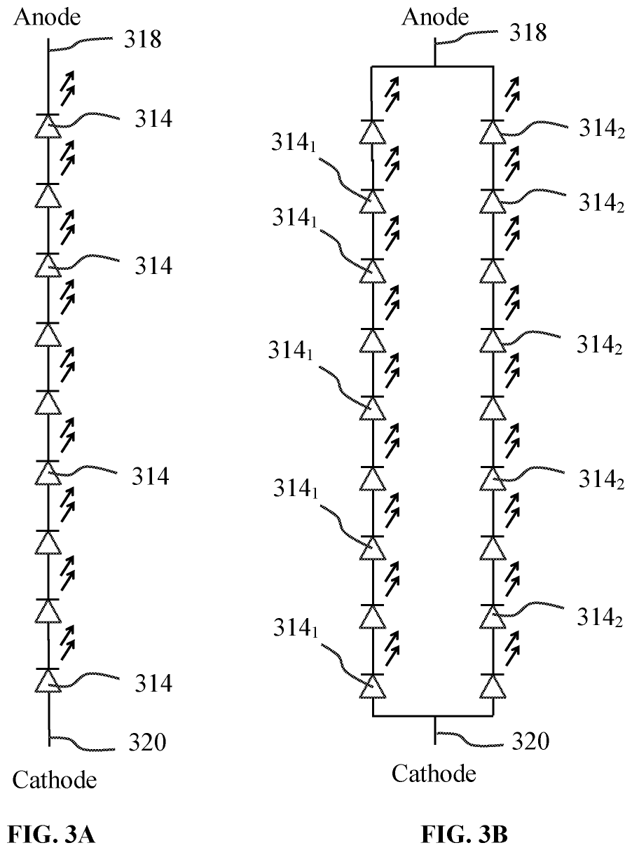

The light emitting device 110 comprises a plurality of LED chips/dies 114 mounted on the top face of the substrate that are be arranged as an array (FIG. 1B). The LED chips comprise GaN-based LEDs that emit light in the blue to violet region of the spectrum. As illustrated, the array of LED chips 114 comprises 165 LED chips (Table 4) that are electrically configured as a string of serially connected LED chips (see FIG. 3A). As shown, the LED chips 114 can be electrically connected by means of bond wires 116. Respective ends of the string of LEDs are electrically connected to a respective anode contact pad 118 and cathode contact pad 120. To generate a desired color temperature of light, the light emitting device comprises layer of phosphor material 122 covering the string of LED chips/dies 114 (FIG. 1A). The layer of phosphor 122 may be contained within an annular wall 124.

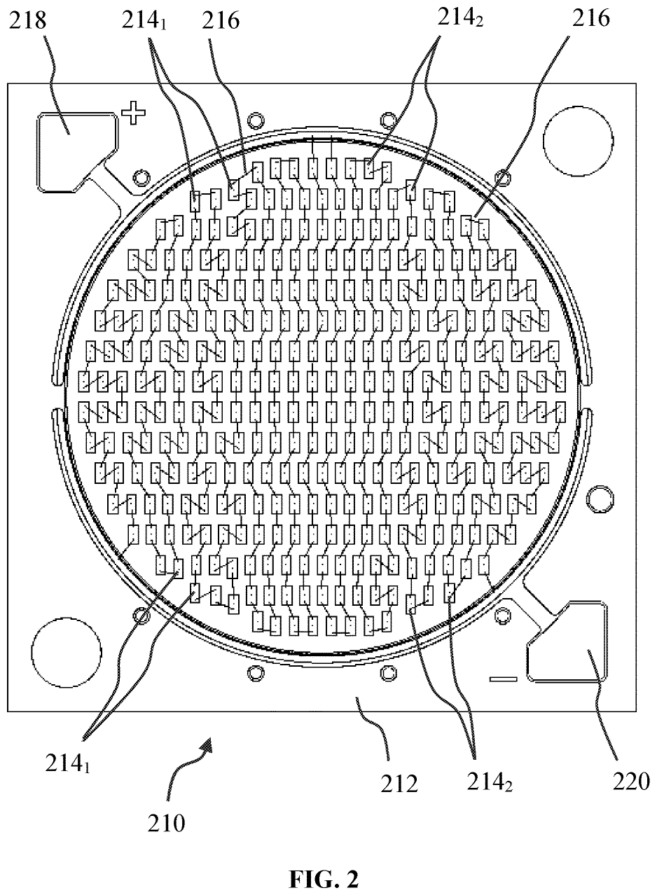

FIG. 2 is a plan view of a light emitting device 210, CoB LED, without phosphor showing the layout of the LED chips, according to an embodiment of the invention. The light emitting device 210 is configured for operation with a nominal drive voltage of 450V (Table 4) and to generate light with a color temperature from 2700K to 6500K. Since the light emitting device 210 is similar to the light emitting device 110 of FIGS. 1A and 1B, only the differences between the devices will be described. The substrate 212 of light emitting device 210 is a square and may be 28 mm by 28 mm (Table 4).

As illustrated, the light emitting device 210 comprises a first string of serially connected first LED chips 214₁ and a second string of serially connected second LED chips, 214₂ (FIG. 2). In FIG. 2 the first string of serially connected first LED chips 214₁ are shown on the lefthand side and the second string of serially connected second LED chips 214₂ are shown on the righthand side. The first string of serially connected first LED chips 214₁ and the second string of serially connected second LED chips 214₂ are electrically connected in parallel (see FIG. 3B). As shown (FIG. 2), the first and second arrays of serially connected LED chips 214₁, 214₂ each comprise 165 LED chips (Table 4). The first and second arrays of serially connected LED chips may comprise the same or substantially the same number of LED chips. In other embodiments they may contain differing numbers of LED chips.

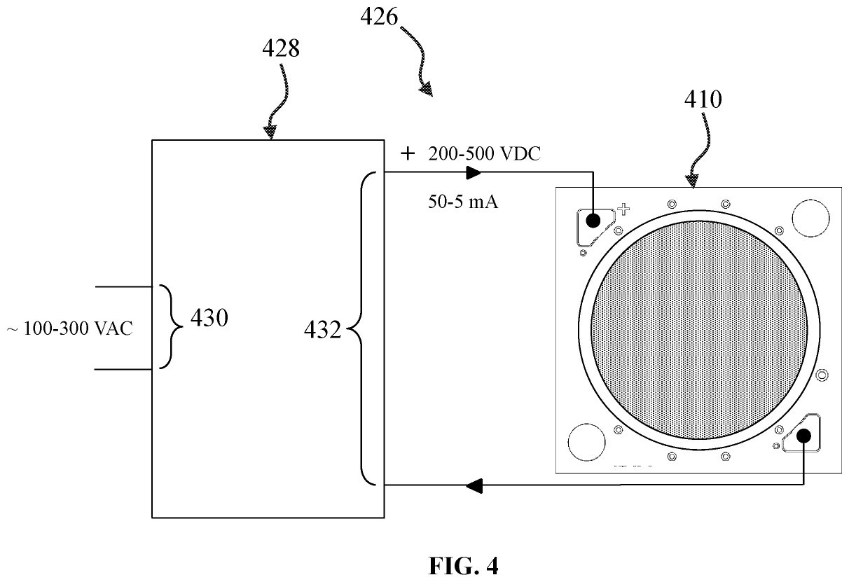

FIG. 4 is a lighting arrangement/system 426 according to an embodiment of the invention. The lighting arrangement/system 426 comprises a light emitting device 410 (as described herein) and a driver 428 for generating a drive voltage from 200 V to 500 V for operating the light emitting device 410. The driver 428 comprises a Driver input 430 for receiving a voltage supply of 100 VAC to 300 VAC, and a Driver output 432 for delivering a drive voltage of 200 VDC to 500 VDC to the light emitting device 410. As described herein, the light emitting device 410 can be configured for operation with a drive voltage in a range from 200 V to 500 V and a drive current in a range from 50 mA to 5 mA. In this embodiment, the lighting arrangement/system 426 has a lumen efficacy of at least 120 lm/W, optionally at least 160 lm/W, and is for generating light of a CRI80 and a color temperature from 2700K to 6500K.

In this specification, the following nomenclature is used to denote light emitting devices: Com. # denotes a comparative light emitting device, and Dev. # denotes a light emitting device in accordance with the invention that is configured for operation with a high drive voltage. Comparative light emitting device Com. 1 is a known CoB LED comprising 24 mm by 24 mm substrate having a string of 12 serially connected LED chips with a nominal drive voltage of 36 V. Dev. 1 is a CoB LED in accordance with the invention comprising 24 mm by 24 mm substrate having a string of 165 serially connected LED chips with a nominal drive voltage of 450 V. Table 1 tabulates test data for comparative device Com. 1, while Table 2 tabulates test data for light emitting device Dev. 1.

A comparison of the test data from Tables 1 and 2 demonstrates that Dev. 1 and Com. 1 each generate approximately the same Lumen Output of 2000 lm (2010 lm and 2067 lm, respectively). However, Dev. 1 uses less power than Com. 1 (10.08 W and 11.48 W, respectively) and exhibits a higher (superior) Lumen (Luminous) Efficacy (199.4 lm/W and 180.0 lm/W, respectively). This demonstrates that a light emitting device according to the invention which is configured to operate with a higher drive voltage (450 V compared with 36 V in known constructions) and a lower drive current (22.4 mA compared with 353 mA) exhibits a superior Lumen (Luminous) Efficacy—that is an increase in Lumen (Luminous) Efficacy of at least 10%. It is understood that the higher drive voltage (a voltage increase by a factor of 12.5×) in combination with the correspondingly greater reduction in drive current (a current reduction by a factor of 15.7×) results in a superior (higher) lumen (luminous) efficacy of the device compared with known constructions that use lower drive voltages and higher drive currents.

TABLE 1
Test data for comparative device Com. 1

| Drive Current | Drive Voltage | Power | Lumen Output | Lumen Efficacy |
|---|---|---|---|---|
| (mA) | (V) | (W) | (lm) | (lm/W) |
| 152 | 31.6 | 4.81 | 905 | 188.4 |
| 201 | 31.9 | 6.40 | 1190 | 185.8 |
| 250 | 32.1 | 8.02 | 1474 | 183.7 |
| 303 | 32.3 | 9.79 | 1780 | 181.8 |
| 353 | 32.5 | 11.48 | 2067 | 180.0 |
| 401 | 32.7 | 13.12 | 2332 | 177.8 |
| 504 | 33.9 | 16.68 | 2904 | 174.1 |

TABLE 2
Test data for light emitting device Dev. 1

| Drive | Drive | | Lumen | Lumen |
|---|---|---|---|---|
| Current | Voltage | Power | Output | Efficacy |
| (mA) | (V) | (W) | (lm) | (lm/W) |
| 6.19 | 432.8 | 2.68 | 563 | 210.1 |
| 9.39 | 436.8 | 4.10 | 855 | 208.4 |
| 13.25 | 441.0 | 5.85 | 1200 | 205.3 |
| 17.62 | 445.2 | 7.85 | 1591 | 202.8 |
| 22.44 | 449.4 | 10.08 | 2010 | 199.4 |
| 27.71 | 453.6 | 12.57 | 2463 | 195.9 |
| 33.21 | 457.8 | 15.20 | 2923 | 192.3 |

Light emitting devices, according to the invention, Devs. 2 to 5 are a CoB LEDs with a nominal drive voltage of 450 V in which: Dev. 2 comprises an 24 mm by 24 mm substrate having a string of 165 serially connected LED chips; Dev. 3 comprises an 24 mm by 24 mm substrate having 2 parallel connected strings each having 165 serially connected LED chips; Dev. 4 comprises an 28 mm by 28 mm substrate having a string of 165 serially connected LED chips; and Dev. 5 comprises an 28 mm by 28 mm substrate having 2 parallel connected strings each having 165 serially connected LED chips.

Referring to Table 3, the inventor understands that the reduction in driver efficiency (95% to 87%) between a device comprising a single string of LEDs and a device comprising at least 2 strings of LEDs connected in parallel is as a result of the increase in drive current.

TABLE 3
Test data for light emitting devices Devs. 2 to 5

| | | Lumen | | | | Lumen | | Driver |
|---|---|---|---|---|---|---|---|---|
| | Power | Output | CCT | CRI | CRI | efficacy | Power | Efficiency |
| Device | (W) | (lm) | (K) | R9 | Ra | (lm/W) | Factor | (%) |
| Dev. 2 | 8.1 | 1500 | 3012 | 71.8 | 95.3 | 185.2 | 0.994 | 95 |
| Dev. 3 | 27.9 | 4069 | 3099 | 71.8 | 95.3 | 146.0 | 0.994 | 87 |
| Dev. 4 | 10.0 | 1937 | 3074 | 65.9 | 93.9 | 193.7 | 0.996 | 95 |
| Dev. 5 | 34.3 | 5107 | 3089 | 71.1 | 95.0 | 149.0 | 0.996 | 87 |

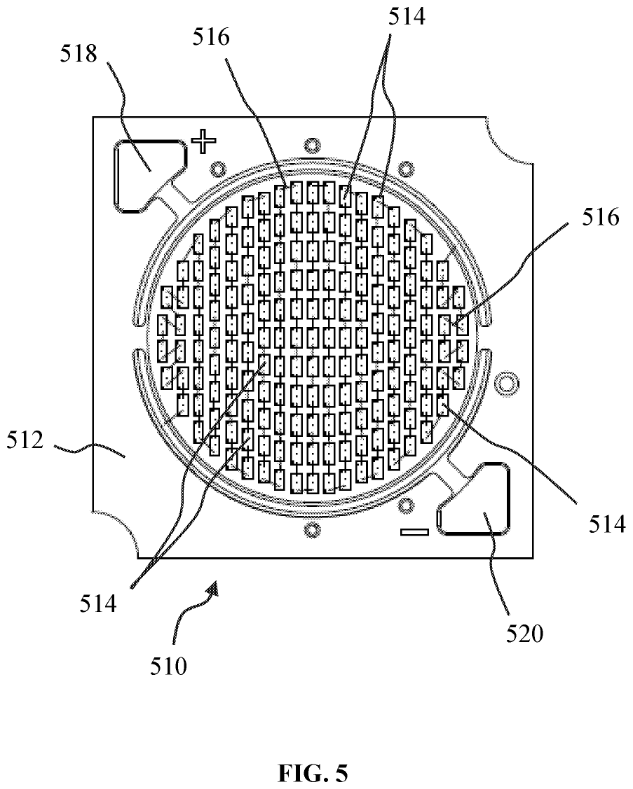

FIG. 5 is a plan view of a light emitting device 510, CoB LED, without phosphor showing the layout of the LED chips, according to an embodiment of the invention. The light emitting device 510 is configured for operation with a nominal drive voltage of 465 V and to generate light with a color temperature from 2700K to 6500K. Since the light emitting device 510 is similar to that of the light emitting device 110 of FIGS. 1A and 1B, only the differences between the devices will be described. The substrate 512 of light emitting device 510 is a square that may be 19 mm by 19 mm. As illustrated, the device comprises a string of 71 serially connected LED chips 514.

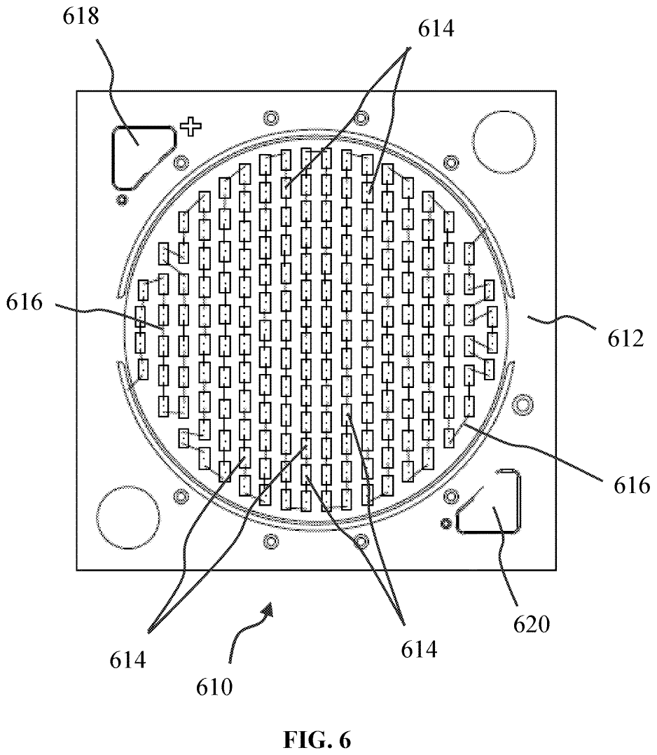

FIG. 6 is a plan view of a light emitting device 610, CoB LED, without phosphor showing the layout of the LED chips, according to an embodiment of the invention. The light emitting device 610 is configured for operation with a nominal drive voltage of 490 V and to generate light with a color temperature from 2700K to 6500K. Since the light emitting device 610 is similar to that of the light emitting device 110 of FIGS. 1A and 1B, only the differences between the devices will be described. The substrate 612 of light emitting device 610 is a square that may be 24 mm by 24 mm. As illustrated, the device comprises a string of 180 serially connected LED chips 614.

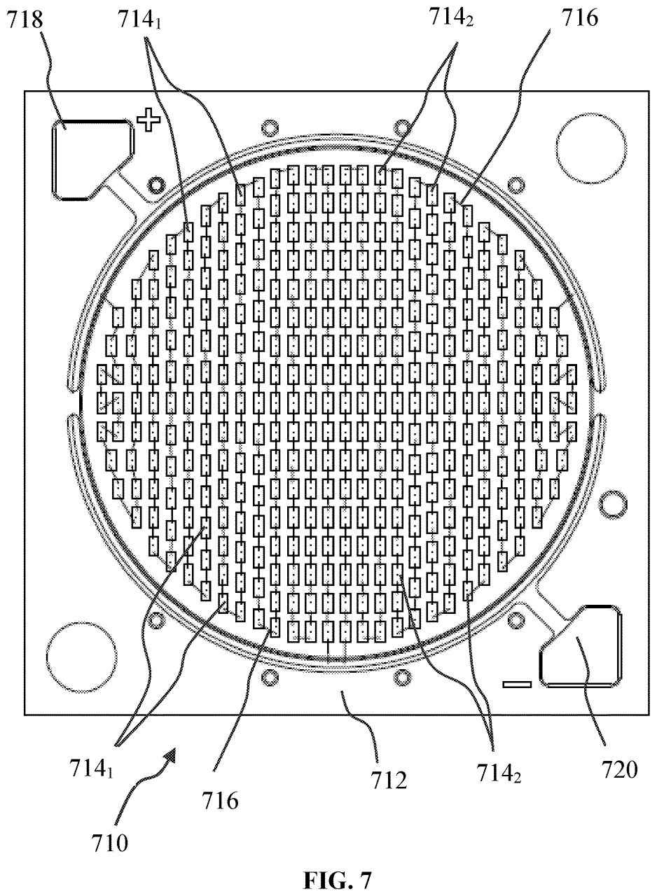

FIG. 7 is a plan view of a light emitting device 710, CoB LED, without phosphor showing the layout of the LED chips, according to an embodiment of the invention. The light emitting device 710 is configured for operation with a nominal drive voltage of 490 V and to generate light with a color temperature from 2700K to 6500K. Since the light emitting device 710 is similar to the light emitting device 110 of FIGS. 1A and 1B, only the differences between the devices will be described. The substrate 712 of light emitting device 710 is a square that may be 28 mm by 28 mm. As illustrated, the light emitting device 710 comprises a first string of serially connected first LED chips 714₁ and a second string of serially connected second LED chips, 714₂ (FIG. 2). In FIG. 7 the first string of serially connected first LED chips 714₁ are shown on the lefthand side and the second string of serially connected second LED chips 714₂ are shown on the righthand side. The first string of serially connected first LED chips 714₁ and the second string of serially connected second LED chips 714₂ are electrically connected in parallel (FIG. 3B). As shown (FIG. 7), the first and second arrays of serially connected LED chips 714₁, 714₂ each comprise 180 LED chips. The first and second arrays of serially connected LED chips may comprise the same or substantially the same number of LED chips. In other embodiments they may contain differing numbers of LED chips.

Table 4 tabulates light emitting device (CoB LED) parameters (number of strings of LED chips, number of LED chips in a string, nominal drive voltage) for CoB LEDs of different size substrates.

TABLE 4
Light emitting device (CoB LED) parameters (number of strings of
LED chips, number of LED chips in a string, nominal drive voltage)
for CoB LEDs of different size substrates.

| Substrate size | LEDs | | Nominal Drive |
|---|---|---|---|
| (mm) | No. Strings | No. LED chips | Voltage (V) |
| 19 by 19 | 1 | 171 | 465 |
| 24 by 24 | 1 | 165 | 450 |
| 24 by 24 | 1 | 180 | 490 |
| 24 by 24 | 2 | 165 | 450 |
| 28 by 28 | 2 | 165 | 450 |
| 28 by 28 | 2 | 180 | 490 |

While the invention has been described in detail, it will be apparent to one skilled in the art that various changes and modifications can be made and equivalents employed, without departing from the present invention. It is to be understood that the invention is not limited to the details of construction, the arrangements of components, and/or the method set forth in the above description or illustrated in the drawings. Further, the figures are merely exemplary and not limiting. Topical headings and subheadings are for the convenience of the reader only. They should not and cannot be construed to have any substantive significance, meaning or interpretation, and should not and cannot be deemed to indicate that all of the information relating to any particular topic is to be found under or limited to any particular heading or subheading. The purpose of the abstract of this document is to enable the U.S. Patent and Trademark Office, as well as readers who are not familiar with patent or legal terms or phraseology, to determine quickly from a cursory inspection the nature of the technical disclosure of the application. The abstract is not intended to define the invention, nor is it intended to limit the scope of the invention. Therefore, the invention is not to be restricted or limited except in accordance with the following claims and their legal equivalents.

Reference numerals (# = FIG. No.)

| | |
|---|---|
| #10 | Light emitting device |
| #12 | Substrate |
| #14 | LED chip/die |
| #16 | Bond wire |
| #18 | Anode contact pad |
| #20 | Cathode contact pad |
| #22 | Phosphor |
| #24 | Annular wall |
| #26 | Lighting system |
| #28 | Driver |
| #30 | Driver input |
| #32 | Driver output |

1. A light emitting device comprising:
a substrate; and
a string of serially connected LED chips on the substrate,
wherein the light emitting device is configured for operation with a drive voltage in a range from 200 V to 500 V.

2. The light emitting device of claim 1, wherein the string of serially connected LED chips comprises from 65 to 195 LED chips.

3. The light emitting device of claim 1, comprising a phosphor material at least partially covering the string of serially connected LED chips.

4. The light emitting device of claim 1, comprising a further string of serially connected LED chips on the substrate.

5. The light emitting device of claim 4, wherein the string and further string of serially connected LED chips comprise substantially a same number of LED chips.

6. The light emitting device of claim 4, wherein the string and further string of serially connected LED chips are connected in parallel.

7. The light emitting device of claim 1, wherein the light emitting device has a lumen efficacy of at least 120 lm/W, optionally at least 160 lm/W, and optionally at least 180 lm/W.

8. A lighting system comprising:
a light emitting device; and
a driver for generating a drive voltage from 200 V to 500 V;
wherein the light emitting device comprises:
a substrate; and
a string of serially connected LED chips on the substrate,
wherein the light emitting device is configured for operation with a drive voltage in a range from 200 V to 500 V and
wherein the lighting system has a lumen efficacy of at least 120 lm/W and is for generating light of a CRI80 and a color temperature from 2700K to 6500K.

9. The lighting system of claim 8, wherein the lighting system has a lumen efficacy of at least 180 lm/W.

10. The lighting system of claim 8, wherein the driver has an efficiency of at least 80%.

11. The lighting system of claim 8, wherein the driver is configured to generate a drive voltage in a range from 400 V to 480 V and has an efficiency of at least 90%.

12. The lighting system of claim 11, wherein the string of serially connected LED chips comprises from 154 to 185 LED chips.

13. The lighting system of claim 8, wherein the driver is configured for operation with a nominal AC input voltage in a range from 100 VAC to 300 VAC.

14. The lighting system of claim 8, wherein the string of serially connected LED chips comprises from 77 to 192 LED chips.

15. The lighting system of claim 8, wherein the light emitting device comprises a phosphor material at least partially covering the string of serially connected LED chips.

16. The lighting system of claim 8, wherein the light emitting device comprises a further string of serially connected LED chips on the substrate.

17. The lighting system of claim 16, wherein the string and further string of serially connected LED chips comprise a same number of LED chips.

18. The lighting system of claim 16, wherein the string and further string of serially connected LED chips are connected in parallel.

19. The lighting system of claim 8, further comprising an optical element comprising at least one of: a lens, a diffuser, or a parabolic reflector.

20. The lighting system of claim 19, further comprising an optics holder.
